(19) United States
(12) Patent Application Publication
(10) Pub. No.: US 2026/0247537 A1
(43) Pub. Date: Aug. 20, 2026

(54) EASY TO REMOVE STANDOFF

(71) Applicant: Quanta Computer Inc., Taoyuan City (TW)

(72) Inventors: Yaw-Tzorng TSORNG, Taoyuan City (TW); Ming-Lung WANG, Taoyuan City (TW); Nan-Chun WU, Taoyuan City (TW); Jia-Lin LIU, Taoyuan City (TW)

(21) Appl. No.: 19/057,790

(22) Filed: Feb. 19, 2025

(51) Int. Cl. H05K 1/183; H05K 1/181

(52) U.S. Cl. CPC H05K 1/183; H05K 1/181; H05K 2201/08; H05K 2201/2036

(57) ABSTRACT

A computing system capable of mounting hardware is provided. The computing system may comprise a printed circuit board (PCB) having a connector and a hardware device communicatively attached to the PCB. The hardware device may have a fastener to secure it to the PCB. The PCB may include a magnet holder physically attached to the PCB and a magnetic standoff for removably coupling the PCB with the hardware device. The magnetic standoff can include a first end attached to the connector of the PCB, and a second end attached to the fastener of the hardware device. The second end of the magnetic standoff can be secured in place by a magnetic force between the magnet holder and the magnetic standoff.

### FIELD OF THE INVENTION

The present invention relates generally to standoffs for mounting a hardware device, and more specifically, to mounting hardware devices within a computing system.

### BACKGROUND OF THE INVENTION

Computing systems, such as server computing systems, may consist of one or more circuit boards located within a housing. These circuit boards may contain various slots, connectors, and interfaces for connecting and installing hardware devices to the circuit board. To fix a hardware device to the circuit board securely, one or more standoffs may be used. A standoff is a spacer or separator that can be placed in between different parts of a computing system. In many computing systems, standoffs are placed in between circuit boards and the system casing. These standoffs often require access to the underside of the circuit board to remove and/or install. In many systems, such as computer towers, computing servers, and rack-mounted equipment, accessing the underside of the circuit boards can be impractical due to the dimensions and/or layout of the system.

Mounting hardware devices may also be difficult due to the differing dimensions of various components of the computing system. Hardware devices may need to be adjusted or rearranged often in the computing system. This process is made more complex because of the difficulty of accessing the underside of the circuit boards of the system.

As such, there is a need for systems, apparatuses, and methods to facilitate more accessible installation of hardware devices in computing systems.

Likewise, modern hardware devices may be designed according to various dimensions, and/or require frequent installation and removal from various locations in the computing system. To install some hardware devices, it may be necessary to make space on the circuit board by moving other hardware devices.

As such, there is also a need for systems, apparatuses, and methods to facilitate more adjustable installation of hardware devices in computing systems.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system capable of mounting hardware is provided. The computing system may comprise a printed circuit board (PCB) having a connector and a hardware device communicatively attached to the PCB. The hardware device may have a fastener to secure it to the PCB. The PCB may include a magnet holder physically attached to the PCB and a magnetic standoff for removably coupling the PCB with the hardware device. The magnetic standoff can include a first end attached to the connector of the PCB, and a second end attached to the fastener of the hardware device. The second end of the magnetic standoff can be secured in place by a magnetic force between the magnet holder and the magnetic standoff.

According to a configuration of the above implementation, the computing system may further comprise a structural case to which the PCB is physically attached. The PCB may remain attached to the structural case when the hardware device is replaced.

According to a configuration of the above implementation, the hardware device may initially be a first hardware device having a first length L1. The first hardware device may be subsequently replaced by a second hardware device having a second length L2 that is different than the first length L1.

According to another configuration of the above implementation, the magnetic standoff may further include a protrusion extending at the second end. In some configurations, the protrusion may be in physical contact with the magnet holder.

According to a further configuration of the above implementation, the magnetic force can be greater than a screwdriver torque of about 5 kilograms-millimeters (kg-mm).

According to another configuration of the above implementation, the magnet holder may be welded on a back side of the PCB.

In a further aspect of the above implementation, the hardware device can be an internally mountable computer expansion card.

In yet a further aspect of the above implementation, the expansion card can be an M.2 expansion card.

According to a further configuration of the above implementation, the M.2 expansion card is an M.2 solid-state drive (SSD).

According to another aspect of the present disclosure, the magnet holder can be an electromagnet operably coupled to the PCB and configured to controllably produce a magnetic field.

In a further aspect of the present disclosure, a method of mounting a hardware device is provided. The method may include adjusting the hardware device to a desired depth and position within a computing system. At least one fastener of the hardware device may be aligned to at least one connector of a printed circuit board (PCB) of the computing system. A first end of at least one magnetic standoff can be inserted into the aligned connector and fastener. A rotational force can be exerted on the at least one magnetic standoff to cause a second end of the magnetic standoff to be secured in place. The second end can be secured in place by a magnetic force between a magnet holder physically attached to the PCB and the at least one magnetic standoff.

According to another configuration of the above implementation, the hardware device can be an internally mounted computer expansion card.

In a further aspect of the above implementation, the expansion card can be a Peripheral Component Interconnect Express (PCIe) expansion card.

In yet a further aspect of the above implementation, the expansion card can be an M.2 expansion card.

In another aspect of the above implementation, the M.2 expansion card can be an M.2 solid-state drive (SSD).

In a further aspect of the above implementation, the hardware device may initially be a first hardware device having a first length L1. The first hardware device may be subsequently replaced by a second hardware device having a second length L2 that is different than the first length L1.

In yet another aspect of the above implementation, the PCB can be physically attached to a structural case. The PCB can remain attached to the structural case when the hardware device is replaced.

According to another configuration of the above implementation, the magnetic force can be greater than a screwdriver torque of about 5 kilograms-millimeters (kg-mm).

According to another configuration of the above implementation, the magnet holder can be an electromagnet operably connected to the PCB and configured to controllably produce a magnetic field.

In a further aspect of the above implementation, the method may further include generating an electric field from the one or more electromagnets by causing an electric current to flow through the electromagnets. This may cause at least one end of at least one standoff to magnetically attach to at least one electromagnet.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is an isometric view showing a circuit board of a computing system, according to certain aspects of the present disclosure.

FIG. 2 is a diagram showing a magnetic standoff of a computing system, according to certain aspects of the present disclosure.

FIG. 3 is a top view of a connector configured to accept a standoff, according to certain aspects of the present disclosure.

FIG. 4 is an isometric view of a circuit board and standoffs of a computing system, according to certain aspects of the present disclosure.

FIG. 5A is a top view of a connector and standoff of a computing system, according to certain aspects of the present disclosure.

FIG. 5B is another top view of a connector and standoff of a computing system, according to certain aspects of the present disclosure.

FIG. 6 is an isometric view of a circuit board, standoffs, and hardware devices of a computing system, according to certain aspects of the present disclosure.

### DETAILED DESCRIPTION

Systems, devices, and methods for mounting hardware devices in a computing system are provided. A computing system may comprise a printed circuit board (PCB) having a connector and a hardware device communicatively attached to the PCB. The hardware device may have a fastener to secure it to the PCB. The PCB may include a magnet holder physically attached to the PCB and a magnetic standoff for removably coupling the PCB with the hardware device. The magnetic standoff can include a first end attached to the connector of the PCB, and a second end attached to the fastener of the hardware device. The second end of the magnetic standoff can be secured in place by a magnetic force between the magnet holder and the magnetic standoff.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

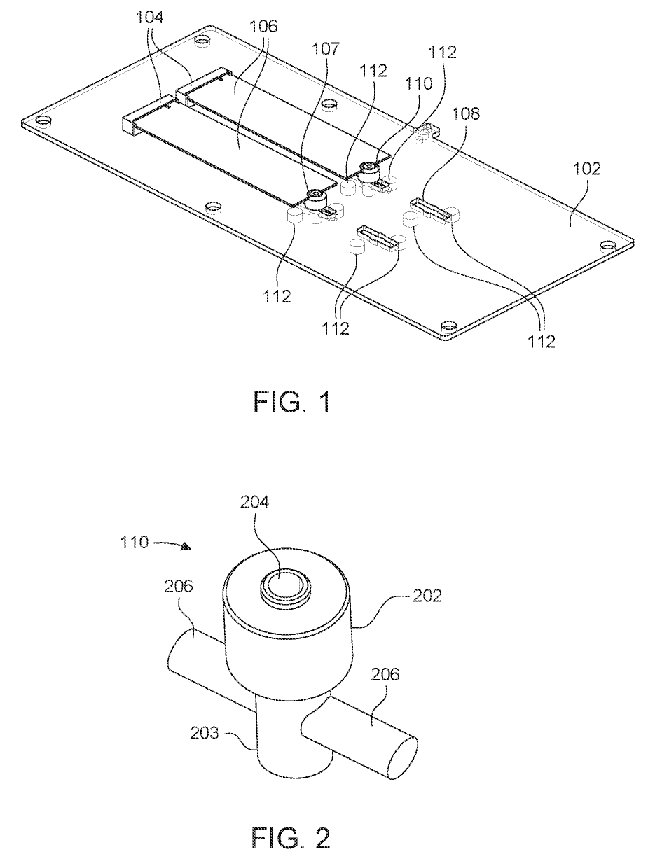

Referring to FIG. 1, A printed circuit board (PCB) 102 is shown. The PCB 102 can be a motherboard, a server board, a computer expansion card, a daughterboard, a graphics card, or another PCB. In some example embodiments, the PCB may be disposed within a housing such as a computer case, mobile device casing, or other housing. In other example embodiments, this housing may be a rack-mount server cabinet or other hardware designed to be used in a computing server environment. The PCB 102 may include one or more interconnectors 104. These interconnectors 104 can be slots, headers, contacts, ports, wireless technologies, or other mechanisms for operably coupling hardware device 106 to the PCB 102. For example, these interconnectors 104 can be Peripheral Component Interconnect (PCI) slots, Peripheral Component Interconnect Express (PCIe) slots, Next Generation Form Factor (M.2) connections, U.2 connectors, or Universal Serial Bus 3.0 (USB 3.0) headers. The interconnectors 104 may be disposed such that hardware device 106 coupled to them extends in a longitudinal direction parallel with respect to the PCB 102.

The hardware device 106 may be various electronic components, storage devices, memory devices, or other equipment designed to operably connect to the PCB 102 by the interconnectors 104. The hardware device 106 may be in various form factors. In some example embodiments, the hardware device 106 can be a computer expansion card meant to be installed longitudinally parallel to the PCB 102. In this exemplary embodiment, the hardware device 106 may include a fastener 107 disposed at an end of the hardware device 106. This fastener 107 may be configured to accept a screw, pin, bolt, clip, standoff, or other fastening device.

The fastener 107 may be aligned with one or more connectors 108 disposed upon the PCB 102. These connectors 108 may be slots, holes, recesses, or other mechanisms fixedly coupled or designed into the PCB 102. Each connector 108 may be configured to accept a standoff 110. The standoff 110 can be a pin, bolt, or other component made of steel, aluminum, plastic, or composite, designed to interface with a connector 108 and a fastener 107.

On the underside of the PCB 102 with respect to the hardware device 106, there may be one or more magnet holders 112 physically attached to the PCB 102. These magnet holders 112 may be positioned proximate to at least a portion of the connectors 108. The magnet holders 112 are configured to engage and adhere magnetically to at least a portion of a standoff 110 inserted into the corresponding connectors 108. In some example embodiments, the magnet holders 112 may be permanent magnets, such as neodymium, samarium cobalt, alnico, or ferrite magnets. In some other example embodiments, the magnet holders 112 can be electromagnets. In this case, the magnet holders 112 may be operably connected to the PCB 102, and they may be controlled and powered by electronic circuitry on the PCB 102. The magnetic field that the magnet holders 112 produce can therefore be controlled, activated, and shut off. In some embodiments, the magnet holders 112 may be controlled in response to a signal sent by the PCB 102. In further embodiments, this signal may be sent in response to the insertion, removal, or rotation of a standoff 110. In other embodiments, this signal may be sent in response to the coupling of hardware device 106 to an interconnector 104.

When hardware device 106 is operably coupled to an interconnector 104, the hardware device 106 may need to be fixed in place. Depending on the dimensions, weight, and position of the hardware device 106, the interconnector 104 may not be capable of securely supporting the hardware device 106 in place. As such, a standoff 110 can be used to support the hardware device 106 in relation to the PCB 102. The standoff can be inserted into a fastener 107 of the hardware device 106, and subsequently inserted into an aligned connector 108 of the PCB 102. In this state, the standoff 110 can still be easily inserted and removed from the connector 108. To lock the standoff 110 in place, a rotational torque force can be applied to a first end of the standoff 110. This may cause at least a portion of the standoff 110 to rotate and engage one or more magnet holders 112. The portion of the standoff 110 may then magnetically adhere to the at least one magnet holder112. This can lock the standoff in place, providing support to the hardware device 106. To fix the hardware device 106 to the standoff 110, a screw or pin may be inserted into the fastener 107 of the hardware device 106, and then inserted into the standoff 110. This will fix the hardware device 106 in place.

Referring to FIG. 2, a diagram of a standoff 110 is provided. The standoff 110 may have a first end 202 and a second end 203. The first end 202 may include a receptacle 204 that is configured to accept a screw, pin, bolt, clip, or other fastening device. The receptacle 204 may be threaded to accept a screw. The screw may be a star screw, a crosshead screw, a flathead screw, a 6-23 screw, an M3 screw, a 4-40 screw, or any other type of screw.

The second end 203 of the standoff 110 may be of a smaller diameter than the first end 202. This may be done to facilitate the interfacing of the second end 203 with a connector 108 of the PCB 102. The second end 203 of the standoff 110 may also be configured to fit only a portion of various sizes of the one or more connectors 108. Protruding perpendicularly with respect to the second end 203, there may be one or more protrusions 206. The protrusions 206 may be of the same material as the second end 203, or a different material. The protrusions 206 may be designed such that when the standoff 110 is inserted into a connector 108 of the PCB 102, the protrusions 206 will rotate under or into the PCB 102 and prevent removal of the standoff 110.

In some embodiments of the present disclosure, the protrusions 206 may be made of a magnetic material such as iron, steel, nickel, cobalt, an alloy of these materials, or any other ferromagnetic substance. When the standoff 110 is inserted into a connector 108 (shown in FIG. 1) and rotated, the protrusions 206 can engage one or more magnet holders 112 (shown in FIG. 1). The one or more magnet holders 112 (shown in FIG. 1) may then exert a magnetic force on the protrusions 206. The magnet holders 112 (shown in FIG. 1) and the protrusions 206 can be configured to have a certain predetermined magnetic field strength between them. This magnetic field may be configured to be stronger than the torque force necessary to insert or remove the fastening device inserted into the receptacle 204 of the standoff 110. This helps to keep the standoff 110 from rotating out of the connector 108 (shown in FIG. 1) when a fastening device is inserted into the receptacle 204.

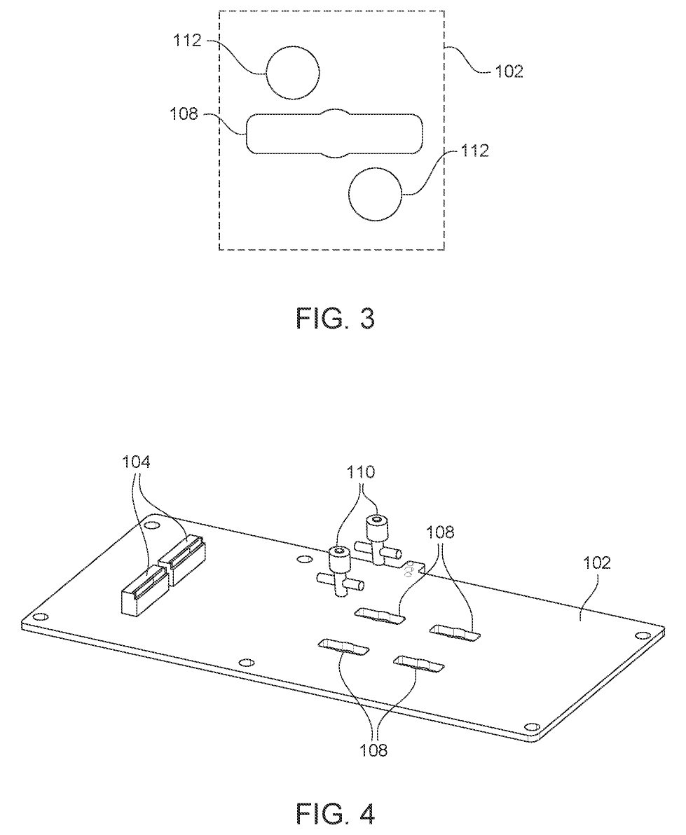

Referring to FIG. 3, a top view of a connector 108 is provided. The connector 108 may be a slot, hole, recess, or other mechanism that can accept a standoff 110. The connector 108 may be shaped to only allow the insertion of a standoff 110 (shown in FIG. 1) at a certain angle or position. The standoff 110 (shown in FIG. 1) can subsequently be rotated to securely fasten it in place with respect to the PCB 102.

The magnet holders 112 may be placed on the underside of the PCB 102 with respect to the connectors 108 (shown in FIG. 1). When the standoff 110 (shown in FIG. 1) is rotated, moving the protrusions 206 (shown in FIG. 2) closer to the magnet holders 112, a magnetic force between the magnet holders 112 and the protrusions 206 (shown in FIG. 2) can hold the standoff 110 (shown in FIG. 1) in place.

Referring to FIG. 4, an isometric view of a computing system is provided. FIG. 4 provides an example view of the insertion process of one or more standoffs 110. One or more standoffs 110 can be inserted into connectors 108 that correspond to the length, depth, or dimension of the hardware device 106. For example, FIG. 4 shows the standoffs 110 being inserted into the pair of connectors 108 closer to the interconnectors 104. This allows for devices to be coupled to the interconnectors 104. To couple devices with different dimensions to the interconnectors 104, the farther pair of connectors 108 can be used. Other positions of connectors 108 and physical arrangements of the hardware device 106 within the computing system are possible.

In some example embodiments, devices coupled to the interconnectors 104 may need more than one connector 108 to be installed onto the PCB 102. In this case, more than one standoff 110 may be used with more than one connector 108.

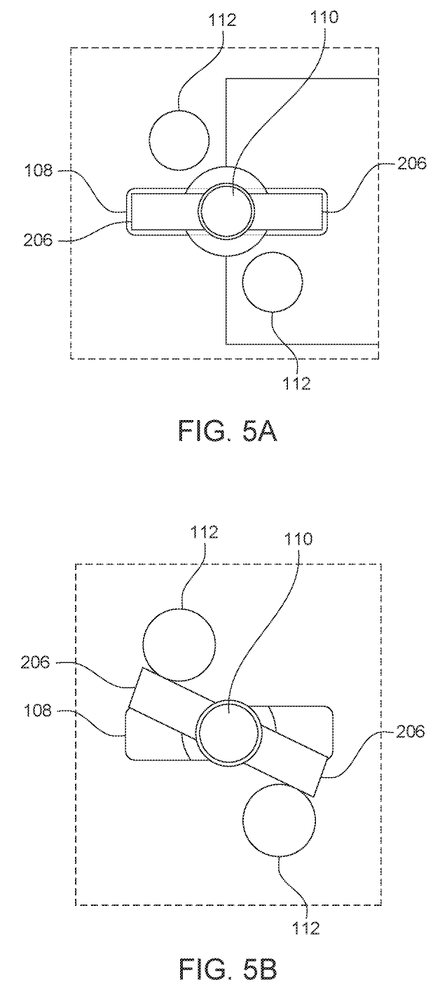

Referring to FIG. 5A, a top view of a standoff 110 inserted into a connector 108 is provided. In this configuration, the protrusions 206 of the standoff 110 are oriented with respect to the connector 108 in a way that allows the standoff 110 to be easily inserted and removed from the connector 108. In this example embodiment, the protrusions 206 are not rotated to be proximate to the magnet holders 112. This means that the protrusions 206 are not magnetically adhered to the magnet holders 112. To remove the standoff 110 from the connector 108, it can be pulled out vertically with respect to the connector 108.

Referring to FIG. 5B, a top view of a standoff 110 inserted into a connector 108 is provided. In this configuration, the standoff 110 has been rotated with respect to the connector 108. This has brought the protrusions 206 into proximity to the magnet holders 112, causing the protrusions 206 to adhere magnetically to the magnet holders 112. In some example embodiments, this can cause the protrusions 206 of the standoff 110 to be disposed under at least a portion of the PCB 102 or solid sections of the connector 108. This locks the standoff 110 in position.

In some embodiments of the present disclosure, the magnet holders 112 may be electromagnets configured to generate a magnetic field in response to a signal. This signal may be generated by the rotation of the protrusions 206 in the connector 108. In some other embodiments, the signal may be generated in response to some other stimuli.

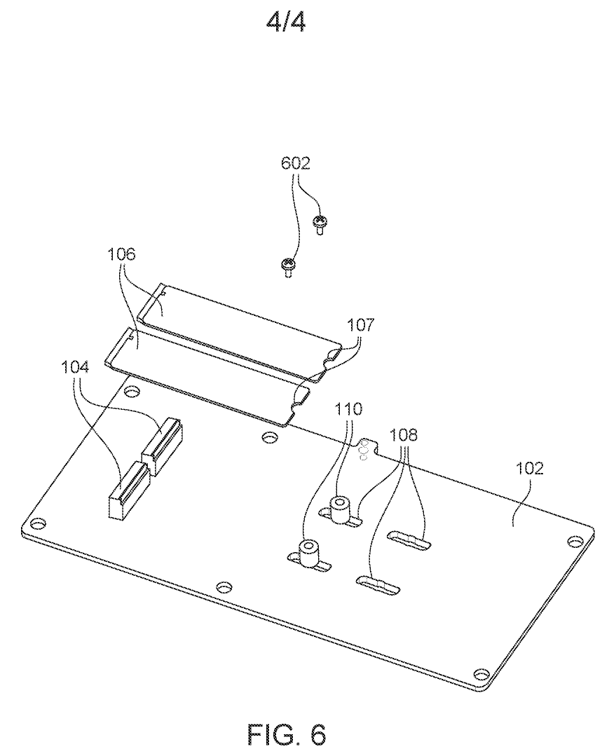

Referring to FIG. 6, is an isometric view of a PCB 102, standoffs 110, and hardware device 106 of a computing system, according to certain aspects of the present disclosure. In this example embodiment, the standoffs 110 have been inserted and locked into the connectors 108. Installing the hardware device 106 to the standoffs 110 may include aligning the hardware device 106 with the interconnectors 104 and the installed standoffs 110. The hardware device 106 can be fixed to the standoffs 110 by one or more screws 602 placed into the hardware device 106 and the standoffs 110. These screws 602 can also be bolts, pins, clips, or other fastening devices. In some embodiments, the standoffs 110 may include a mechanism integral to the standoffs 110 that fixes the hardware device 106 in place without the need for the screws 602.

In some embodiments of the present disclosure, the standoffs 110 can be used to facilitate the easy removal of the hardware device 106. In these embodiments, the hardware device 106 may be installed and fixed in position with respect to the PCB 102 using the standoffs 110. To remove the hardware device 106, the screws 602 can be removed, uncoupling the hardware device 106 from the standoffs 110. The magnet holders 112 can be configured to exert a magnetic force on the standoffs 110 greater than the force necessary to remove the screws 602 from the standoffs 110. This allows the standoffs 110 to stay locked with respect to the PCB 102 while removing the screws 602.

In response to a force sufficient to uncouple the screws 602 from the standoffs 110, the screws 602 may be removed from the standoffs 110. This allows for the hardware device 106 to be uncoupled from the standoffs 110 and the interconnectors 104. The hardware device 106 can then be uninstalled from the PCB 102. In some example embodiments, this process may further include rotating the standoffs 110 to disengage the standoffs 110 from the magnet holders 112 and allow for the standoffs 110 to be removed from the connectors 108.

In further example embodiments of the present disclosure, the standoffs 110 can then be modified, switched out, or moved to other connectors 108. For example, at least one of the standoffs 110 could be moved to one of the connectors 108 in the PCB 102 that are farther from the interconnectors 104. This can allow for hardware devices with certain dimensions to be installed onto the PCB 102. Other configurations of the standoffs 110 and the connectors 108 with respect to the interconnectors 104 and the PCB 102 are possible.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing system comprising:
a printed circuit board (PCB) having a connector;
a hardware device communicatively attached to the PCB, the hardware device having a fastener;
a magnet holder physically attached to the PCB; and
a magnetic standoff for removably coupling the PCB to the hardware device, the magnetic standoff having
a first end attached to the connector of the PCB, and
a second end attached to the fastener of the hardware device, the second end being secured in place by a magnetic force between the magnet holder and the magnetic standoff.

2. The computing system of claim 1, further comprising a structural case to which the PCB is physically attached, the PCB remaining attached to the structural case when the hardware device is replaced.

3. The computing system of claim 2, wherein the hardware device is initially a first hardware device having a first length L1, the first hardware device being subsequently replaced by a second hardware device having a second length L2 that is different than the first length L1.

4. The computing system of claim 1, wherein the magnetic standoff further includes a protrusion extending at the second end, the protrusion being in physical contact with the magnet holder.

5. The computing system of claim 1, wherein the magnetic force is greater than a screwdriver torque of about 5 kilograms-millimeters (kg-mm).

6. The computing system of claim 1, wherein the magnet holder is welded on a back side of the PCB.

7. The computing system of claim 1, wherein the hardware device is an internally mountable computer expansion card.

8. The computing system of claim 7, wherein the expansion card is an M.2 expansion card.

9. The computing system of claim 8, wherein the M.2 expansion card is an M.2 solid-state drive (SSD).

10. The computing system of claim 1, wherein the magnet holder is an electromagnet operably connected to the PCB and configured to controllably produce a magnetic field.

11. A method of mounting a hardware device comprising:
adjusting the hardware device to a desired depth and position within a computing system;
aligning at least one fastener of the hardware device to at least one connector of a printed circuit board (PCB) of the computing system;
inserting a first end of at least one magnetic standoff into the aligned connector and fastener; and
exerting a rotational force to the at least one magnetic standoff to cause a second end of the magnetic standoff to be secured in place by a magnetic force between a magnet holder physically attached to the PCB and the at least one magnetic standoff.

12. The method of claim 11, wherein the hardware device is an internally mounted computer expansion card.

13. The method of claim 12, wherein the expansion card is a Peripheral Component Interconnect Express (PCIe) expansion card.

14. The method of claim 12, wherein the expansion card is an M.2 expansion card.

15. The method of claim 14, wherein the M.2 expansion card is an M.2 solid-state drive (SSD).

16. The method of claim 11, wherein the hardware device is initially a first hardware device having a first length L1, the first hardware device being subsequently replaced by a second hardware device having a second length L2 that is different than the first length L1.

17. The method of claim 11, wherein the PCB is physically attached to a structural case, the PCB remaining attached to the structural case when the hardware device is replaced.

18. The method of claim 11, wherein the magnetic force is greater than a screwdriver torque of about 5 kilograms-millimeters (kg-mm).

19. The method of claim 11, wherein the magnet holder is an electromagnet operably connected to the PCB and configured to controllably produce a magnetic field.

20. The method of claim 19, further comprising generating an electric field from the one or more electromagnets by causing an electric current to flow through the electromagnets, thereby causing at least one protrusion of at least one standoff to magnetically attach to at least one electromagnet.
